(19) United States
(12) Patent Application Publication
(10) Pub. No.: US 2005/0058769 A1
(43) Pub. Date: Mar. 17, 2005

(54) Method for insulation of a superconductor

(75) Inventors: Thomas Arndt, Hanau (DE); Andre Aubele, Hanau (DE); Martin Munz, Alzenau (DE); Bernd Sailer, Alzenau (DE); Andreas Szulczyk, Linsengericht (DE)

Correspondence Address: Andreas Grubert;Baker Botts L.L.P., One Shell Plaza, 910 Louisiana, Houston, TX, 77002-4995, US

(73) Assignee: European advanced Superconductors GmbH & Co. KG

(21) Appl. No.: 10/926,605

(22) Filed: Aug. 26, 2004

Related U.S. Application Data
(63) Continuation of application No. PCT/EP03/01753, filed on Feb. 20, 2003.

(30) Foreign Application Priority Data
Feb. 26, 2002 (DE) 102 08 139. 5

(51) Int. Cl. B05D 5/12; H01L 39/00

(52) U.S. Cl. 427/62; 505/100

(57) ABSTRACT

A method for the production of an allover covering made of an electric insulation material made of plastic disposed around at least one superconductor comprises the steps of making a flexible tube of a melted thermoplastic insulation material which is extruded on the surface of the superconductor. In order to obtain a mechanical reinforcement, a portion of fibres of a fibrous material are added to the thermoplastic insulation material.

### CROSS REFERENCE TO RELATED APPLICATION

This application is a continuation of copending International Application No. PCT/EP03/01753 filed Feb. 20, 2003 which designates the United States, and claims priority to German application no. 102 08 139.5 filed Feb. 26, 2002.

### TECHNICAL FIELD OF THE INVENTION

The invention relates to a method for manufacturing an all-around envelope from an electrical insulating material made of plastic enveloping at least one superconductor in which a molten/fused tube made of a fused thermoplastic insulating material is extruded onto the surface of the superconductor. Such a method is known for example from WO 00/11684.

### BACKGROUND OF THE INVENTION

This method is a continuous enveloping process at a process temperature that practically does not interfere with the superconducting properties of the superconductor. In this process the superconductor is extruded out of a guide channel extending along one thrust direction. The fused tube made of fused thermoplastic insulating material is extruded in the thrust direction from a jet whose exit opening envelops the superconductor, keeping it away from everything else. The molten/fused tube stretches with the thrust of the superconductor and is pulled over the surface of the superconductor, upon which the fused tube solidifies on the surface of the superconductor as it cools.

In this known method the application of an envelope made of thermoplastic material is accomplished in the thin-film extrusion technology according to the so-called tube stretch procedure. In it a fused tube is extruded from a jet whose dimensions are larger than the superconductor to be enveloped, which runs through a central guide channel along the center of the jet. This creates a tube around the superconductor that is stretched, i.e. elongated with the thrust of the superconductor until the final, desired thickness (strength) of the envelope wall (insulating layer) is reached.

This tube is pulled over the superconductor surface. Depending on the insulating material used, the so-called stretch degree, i.e. the elongation of the material, is generally between 5 and 15.

The stretching can best be accomplished by the simultaneous effect of a vacuum in the interior of the tube. This, together with a desirable pre-heating of the superconductor before entry into the guide channel and/or during the time the superconductor is pulled through the channel, creates a particularly tight and bubble-free fit of the envelope around the superconductor. The subsequent slow cooling, e.g. exposure to air, causes freezing and a stress-free fit of the fused material made of insulating material on the superconductor.

This insulating method known from the state of the art, however, has the serious disadvantage that the insulating layers plus any mechanical reinforcement layers are relatively thick, reducing thereby the total current density of the superconductor. Because of the overall increase in total current density in high-temperature superconductor over time, the Lorentz force load also increases. Depending on the use, the prevailing Lorentz forces can be so strong that the total current densities are irreversibly reduced.

### SUMMARY OF THE INVENTION

The objective of the present invention is therefore to improve the insulating method of the type mentioned above in the sense that the total current density in the application increases noticeably, or that there are no degradation effects in the application.

The invention achieves this objective by mixing the short fibers of a fibrous material into the thermoplastic insulating material in the procedure mentioned above.

By using the short fibers of a fibrous material the total current density is therefore not reduced by the mechanical reinforcement and the separate insulation, but instead the two required actions are undertaken in the same cross section portion of the insulated and reinforced superconductor. By adding fibrous materials to the insulating material the superconductor can be subjected to much higher stretch stress and mechanical stress.

In a preferred embodiment glass fiber material is used as the fibrous material (high electrical insulating properties), however—depending on the requirements of the application—aramid materials or carbon fiber materials (less electrical insulating properties) are also conceivable. Furthermore, haphazardly oriented individual fibers, fibers parallel to the thrust direction or a fiber netting can be used.

Typically, the short fibers have a length of about 20-30 mm. Depending on the desired thickness of the insulating layer and the netting of the fibers, much shorter or longer nettings, or even full nettings, are also possible.

Typically polyethylene, elastomers of polystyrene-ethylene-butylene, polyurethane elastomers, ethylene-vinyl acetate-copolymer or acrylic acid-acrylate-copolymer are used as thermoplastic materials that are the basis of the insulating material.

The aspect ratios that are achievable with the method according to the invention are at least 2.5, preferably however at least 8. At least one superconductor with oxidix high-temperature superconducting material can be provided with an envelope. The band-shaped superconductor may have a maximum band thickness of 0.5 mm. The band-shaped superconductor may have several conductor cores made of superconducting material embedded in normally conducting material. The method can also be used for enveloping a superconducting multiple or group conductor that has at least one superconducting individual conductor or super conductor core.

### BRIEF DESCRIPTION OF THE DRAWING

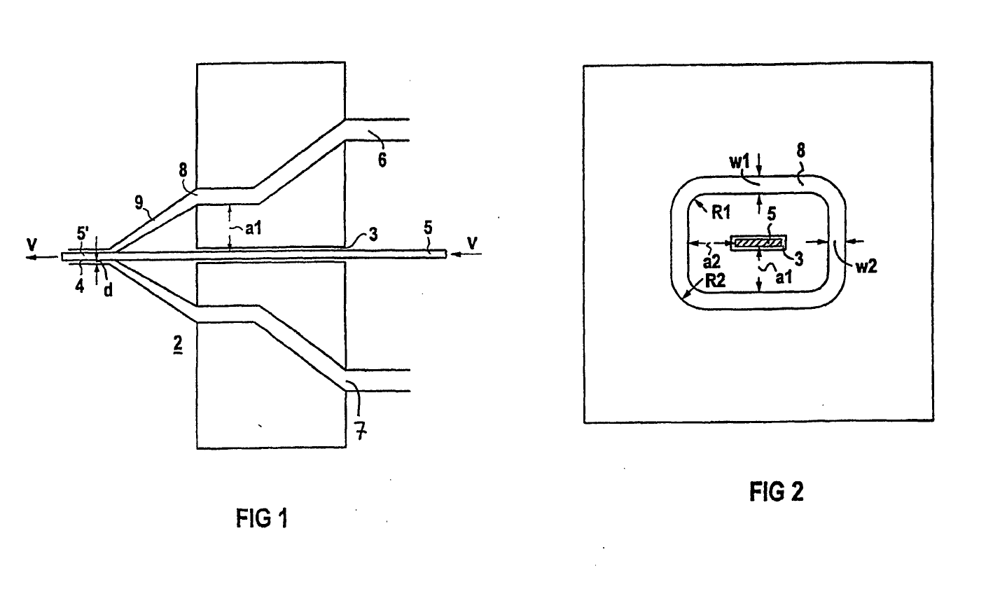

The invention is explained in detail below using examples of embodiment. In it FIG. 1 and FIG. 2 show schematically a jet for setting up the method according to the invention as a longitudinal section or in a frontal view.

### DESCRIPTION OF THE INVENTION

Corresponding parts in the illustrations are shown with the same reference numbers. Parts that are not shown are known from the current state of the art. The method is implemented using a facility containing a so-called extruder with an extrusion head that has the extrusion jet shown in longitudinal section or frontal view in FIGS. 1 and 2. This jet, generally designated as 2, has a guide channel 3 in the middle. Through this channel a superconductor 5 featuring an electrically insulated envelope 4 is to be conveyed in a thrust direction indicated with the arrow v using a propulsion device (not shown). According to the chosen example of embodiment the superconductor 5 is a band-shaped high-temperature superconductor. This superconductor is best preheated before being inserted into the guide channel 3. Alternatively, the guide channel itself can be heated instead or additionally.

The insulating material of the envelope 4 is sintered in the extruder, which is not shown, conveyed to the extrusion head per distributing system and pressed as fused material 6 into a jet orifice 7 of the extrusion jet 2.

The insulating material in this case is a thermoplast that initially has the form of a granulate. Typical thermoplasts are polyethylene, polyurethane or various copolymers. The thermoplast granulate is preferably mixed with short fibers.

At an exit opening 8 of the jet orifice 7, whose orifice width at that point is noticeably larger than the final thickness d of the envelope 4 around the strip line 5, a fused tube 9 exits in the thrust direction v that is stretched in the form of a stretch cone because its cone point is attached to the band-shaped superconductor and is applied to the superconductor with the layer thickness d required for the band-shaped superconductor. A vacuum generated in the guide channel 3 creates negative pressure inside the stretch cone that prevents air bubbles from forming between the envelope and the superconductor and that, together with the preheated superconductor, guarantees a good fit of the envelope 4 on the superconductor. The band-shaped superconductor enveloped in that way is shown in FIG. 1 with reference 5′.

As can be seen from FIG. 2, the jet orifice opening 8 preferably has a shape that is adapted to the contour of the band-shaped superconductor 5. The therefore primarily rectangular opening with rounded corners has the distances a1 and a2 relative to the surfaces of the band-shaped superconductor and is defined in its key areas by the orifice widths w1 and w2 as well as the curvature radii R1 and R2. The distances (a1, a2) of the jet orifice opening 8 from the strip line 5, whose geometric shape (w1, w2, R1, R2) and propulsion speed v of the superconductor determine the contour of the envelope 4 and its thickness d.

As shown in the embodiment example according to FIG. 2, the geometric shape of the extrusion jet can be chosen in such a way that the thickness d of the envelope 4 is about the same on all sides, with the thickness d generally planned being less than 0.5 mm, for example between 10 and 300 μm.

All those thermoplastic materials that, while having a process or melting temperature that prevents any interference with the superconductor properties of the superconductor to be enveloped, in particular of the high-temperature superconductor 5, still guarantee enough plasticity for the extrusion layering process can be used as insulating plastic materials for envelope 4.

In principle, processing temperatures above approx. 400° C. are not suitable for enveloping high-temperature superconducting materials based on bismuth-cuprate of the 2223 type and embedded in silver (depending on the atmospheric conditions). In this case, therefore, thermoplastic materials are used containing e.g. a corresponding polyethylene, a corresponding polystyrene-ethylene-butylene-elastomer, a corresponding polyurethane-elastomer, a corresponding ethylene/vinyl acetate-copolymer or an acrylic acid/acrylate-copolymer. If a transparent insulating material such as a thermoplastic polyurethane elastomer is used, the insulating envelope can also be colored with dyes. These mentioned thermoplasts are mixed with fibers, such as carbon fibers available under the trade name Grafil34-700, Pyrofil TR50, Torayca T700 or Panex 33. However, the preference is for aramids or E-glass such as fiber glass or Aramid-Twaron 2200.

The thin-film or extrusion layering method according to the invention is above all suitable for enveloping band-shaped high-temperature superconductors whose strip line thickness is below 1.5 mm, preferably below 0.5 mm and that have a high aspect ratio of at least 2.5, preferably at least 8. For example, such a band-shaped high-temperature superconductor can have a width of 3.6 mm and a thickness of 0.25 mm. All known oxidic superconductor materials with high transition temperatures can be considered as high-temperature superconductor materials, in particular those that allow cooling with the use of liquid nitrogen. Materials based on copper and copper oxide or bismuth cuprates can be considered as especially suitable, but also the conventional metallic superconductor and high-temperature superconductors in thin-film form on a band-shaped carried are suitable for this procedure.

The examples of embodiment made the assumption that the superconductors to be coated are band-shaped high-temperature superconductors. While the method according to the invention is of great advantage for enveloping such superconductors, it can be used equally well for superconductors of the “classic” kind, namely for superconductors based on niobium, e.g. Nb3Sn or Nb3Ge, or NbTi, or also for high-temperature superconductors in thin-film form on a band-shaped carrier (e.g. Yba2Cu3Ox with possible buffer layers on texturized nickel bands or steel bands).

1. A method for manufacturing an all-around envelope from an electrical insulating material made of plastic enveloping at least one superconductor comprising the step of:
extruding a fused tube made of fused thermoplastic insulating material onto the surface of the superconductor, wherein the thermoplastic insulating material is mixed with short fibers of a fibrous material.

2. The method according to claim 1, wherein a glass fiber material is used as the fibrous material.

3. The method according to claim 1, wherein haphazardly oriented individual fibers, fibers parallel to the thrust direction or a fiber netting is used.

4. The method according to claim 1, wherein a polyethylene, a polystyrene-ethylene-butylene-elastomer, a polyurethane elastomer, an ethylene-vinyl acetate-copolymer or an acrylic acid-acrylate-copolymer are used as thermoplastic insulating material.

5. The method according to claim 1, wherein at least one superconductor with oxidix high-temperature superconducting material is provided with an envelope.

6. A method for enveloping a band-shaped superconductor comprising the step of:
extruding a fused tube made of fused thermoplastic insulating material onto the surface of the superconductor, wherein the thermoplastic insulating material is mixed with short fibers of a fibrous material.

7. The method according to claim 6, wherein a glass fiber material is used as the fibrous material.

8. The method according to claim 6, wherein haphazardly oriented individual fibers, fibers parallel to the thrust direction or a fiber netting is used.

9. The method according to claim 6, wherein a polyethylene, a polystyrene-ethylene-butylene-elastomer, a polyurethane elastomer, an ethylene-vinyl acetate-copolymer or an acrylic acid-acrylate-copolymer are used as thermoplastic insulating material.

10. The method according to claim 6, wherein at least one superconductor with oxidix high-temperature superconducting material is provided with an envelope.

11. The method according to claim 6, wherein the band-shaped superconductor has an aspect ratio of at least 2.5.

12. The method according to claim 6, wherein the band-shaped superconductor has an aspect ratio of at least 8.

13. The method according to claim 12, wherein the band-shaped superconductor has a maximum band thickness of 2.5 mm.

14. The method according to claim 12, wherein the band-shaped superconductor has a maximum band thickness of 0.5 mm.

15. The method according to claim 13, wherein the band-shaped superconductor has several conductor cores made of superconducting material embedded in normally conducting material.

16. The method according to claim 14, wherein the band-shaped superconductor has several conductor cores made of superconducting material embedded in normally conducting material.

17. A method for enveloping a superconducting multiple or group conductor that has at least one superconducting individual conductor or super conductor core comprising the step of:
extruding a fused tube made of fused thermoplastic insulating material onto the surface of the superconductor, wherein the thermoplastic insulating material is mixed with short fibers of a fibrous material.

18. The method according to claim 17, wherein a glass fiber material is used as the fibrous material.

19. The method according to claim 17, wherein haphazardly oriented individual fibers, fibers parallel to the thrust direction or a fiber netting is used.

20. The method according to claim 17, wherein a polyethylene, a polystyrene-ethylene-butylene-elastomer, a polyurethane elastomer, an ethylene-vinyl acetate-copolymer or an acrylic acid-acrylate-copolymer are used as thermoplastic insulating material.

21. The method according to claim 17, wherein at least one superconductor with oxidix high-temperature superconducting material is provided with an envelope.
